(19) United States
(12) Patent Application Publication
(10) Pub. No.: US 2020/0086346 A1
(43) Pub. Date: Mar. 19, 2020

(54) SELF-CLEANING USING TRANSPARENT ULTRASONIC ARRAY

(71) Applicant: Innovasonic Inc., Dublin, CA (US)

(72) Inventors: Boris Kobrin, Dublin, CA (US); Julian Zegelman, San Francisco, CA (US)

(21) Appl. No.: 16/690,028

(22) Filed: Nov. 20, 2019

Related U.S. Application Data
(63) Continuation-in-part of application No. 15/645,991, filed on Jul. 10, 2017.
Application No. 15/645,991 is a continuation of application No. PCT/US2016/021836, filed on Mar. 10, 2016.
Application No. PCT/US2016/021836 is a continuation of application No. PCT/US2016/015448, filed on Jan. 28, 2016.
(60) Provisional application No. 62/774,801, filed on Dec. 3, 2018.
(60) Provisional application No. 62/770,358, filed on Nov. 21, 2018.
(60) Provisional application No. 62/117,906, filed on Mar. 16, 2015.

(51) Int. Cl. B06B 1/06; H01L 41/047; B60S 1/02; A42B 3/24; A42B 3/26; G02B 27/00

(52) U.S. Cl. CPC B06B 1/0629; H01L 41/047; G02B 27/0006; A42B 3/24; A42B 3/26; B60S 1/02

(57) ABSTRACT

An active self-cleaning device for transparent substrates includes a transparent substrate, a piezoelectric transducer array formed on essentially entire transparent substrate surface, including a central area of the transparent device, and an electronic system configured to actuate the piezoelectric transducer array to clean a surface of the substrate. Such a device may be used for applications such as LIDAR, radar and camera enclosures, solar cell panel cover glasses, vehicle windshields, windows, sunroofs and headlamps, street lighting and information displays.

### 1. CLAIM OF PRIORITY

This Application is a continuation-in-part of U.S. patent application Ser. No. 15/645,991, filed Jul. 10, 2017, the entire contents of which are incorporated herein by reference. U.S. patent application Ser. No. 15/645,991 is a continuation of International Patent Application Number PCT/US2016/021836, filed Mar. 10, 2016, the entire contents of which are incorporated herein by reference. International Patent Application Number PCT/US2016/021836 is a continuation of International Patent Application Number PCT/US2016/015448, filed Jan. 28, 2016, the entire contents of which are incorporated herein by reference. International Patent Application Number PCT/US2016/021836 claims the priority benefit of U.S. Provisional Patent application 62/117,906 filed Mar. 16, 2015, the entire contents of which are incorporated herein by reference. This application also claims the priority benefit of U.S. Provisional Patent Application No. 62/774,801 filed Dec. 3, 2018, the entire contents of which are incorporated herein by reference. This application also claims the priority benefit of U.S. Provisional Patent Application No. 62/770,358, filed Nov. 21, 2018, the entire contents of which are incorporated herein by reference.

### 2. FIELD OF THE DISCLOSURE

The present disclosure relates to ultrasonic transducers and more particularly to transparent ultrasonic transducer array for self-cleaning of optical components, like windows, windshields, glass covers, lenses, etc. in a variety of products, like transportation vehicles, cameras, Light Detection and Ranging Devices (LIDARs), telescopes, prescription and sunglasses, visors, goggles, displays, headlamps, street lighting, and other devices.

### 3. BACKGROUND

Ultrasonic transducers are widely used to clean surfaces from contamination. Usually this process is done in a bath of cleaning liquid, exposed to ultrasonic energy directed from ultrasonic transducers, and in order to clean the product one need to immerse it in a liquid and keep it for some time. Obviously, this cleaning process has no use for cleaning car's windshield, LIDAR's enclosure, solar panel enclosure, or buildings windows during operation of these devices.

Cleaning of Windshields:

The windshields of transportation vehicles have been cleaned using movable mechanical devices—wipers—for more than a century now.

The concept of ultrasonic wiperless windshield cleaning can be traced back to the early 1960s. U.S. Pat. No. 3,171,683 (filed in 1963) covers Arthur Ludwig's concept for a “Windshield assembly for motor vehicles and the like.”

In essence, the transducers shake the glass, so that rain, snow, mud, etc. do not stick. However, there appears to be no evidence that the concept was ever demonstrated.

The next significant advance in ultrasonic windshield cleaners was made by Kenro Motoda. His approach, as recorded in U.S. Pat. No. 4,768,256 (filed in 1986), looks rather like Ludwig's, in that there are a set of ultrasonic transducers fixed onto the windshield. However, his transducers are actually launchers for surface acoustic waves. Unlike conventional vibrations, which generally produce a pattern of standing (stationary) waves on the surface of the glass, surface acoustic waves move the surface of the glass in an elliptical pattern that propagates across the glass, hopefully carrying along with it water, dirt, and other muck obscuring the driver's view. While the progressive motion of the surface acoustic waves should be more effective than the simple shaking of the Ludwig design, it appears that Motoda's design was never produced.

A number of modifications of Motoda's basic design were patented over the years, including one that involved the piezoelectric polymer polyvinylidine fluoride being sandwiched between transparent conducting electrodes to generate the surface acoustic waves, (Broussoux et al, U.S. Pat. No. 5,172,024 (1990)); as well as applications to cleaning semiconductor wafers (Akatsu et al., U.S. Pat. No. 6,021,789 (1998)), and for shaking dust from camera optics (Urakami et al., U.S. Pat. No. 8,063,536 (2009).

The most recent patent activity in this field is described in International Patent Application Publication WO2012095643, filed in 2011 by a small UK engineering firm, Echovista Systems Ltd. While the basic technique is still that of Motoda, the Echovista publication has expanded the possible modes of usage to include ultrasonic vaporization of precipitation from the windshield, the use of other vibrational modes which may be more effective in removing precipitation, using the heating of the windshield caused by the ultrasonic vibration to melt ice and snow and de-fog the windshield, and the use of a windshield washing liquid nozzle, having an effect similar to plunging the windshield into an ultrasonic cleaner. Echovista also appears to have done significant testing on its ultrasonic washer, identifying maximum effectiveness is obtained with an ultrasonic frequency of about 2 MHz, corresponding to an ultrasonic wavelength of about 2.5 mm (0.1 in).

Obviously, all prior art had to position their “macro” ultrasonic transducers 1, 2, 3, 4, 5, 6, 7, 8, on the periphery 9 of the window/windshield 10 to be cleaned (not to obstruct a view) which is shown on FIG. 1. In order to clean a specific place on the large windshield an ultrasonic energy should travel from the edge to the point of application, which causes significant loss of energy and as a result requires larger US power.

Cleaning of Architectural Windows:

Similar ultrasonic devices could be used to clean solar panels and architectural windows from contamination. Vasiliev used macro-ultrasonic device located outside of the working area of the solar panel. See Piotr Vasiljev, Sergejus Borodinas, Regimantas Bareikis, Arunas Struckas, “Ultrasonic System for Solar Panel Cleaning”, Sensors and Actuators A 200 (2013) pp. 74-78, Jan. 14, 2013, Elsevier B. V. Ultrasonic cleaning is a very important and economically efficient solution, since allows to significantly boost efficiency of energy generation, avoid using manual labor or expensive robotics.

Efficiency of cleaning could be much higher and power requirements much lower if ultrasonic transducers could be positioned in very close proximity to or even right at the point of contamination within a viewing/exposure area of a windshield, window, sunroof or solar panel. But for this to happen such transducer must be not only very transparent, but in case of a windshield, absolutely invisible to the human eye from a short distance of viewing within a vehicle.

Cleaning of LIDAR Devices:

The self-driving car industry has been experiencing very active growth in the last few years. The essential part of the self-driving system is LIDAR, which is a surveying method that measures distance to a target by illuminating that target with a pulsed laser light, and measuring the reflected pulses with sensor. Differences in laser return times and wavelengths can then be used to make digital 3D-representations of the target.

Efficiency and accuracy of range data depends strongly on the cleanliness of the surface. Unfortunately, LIDAR systems for self-driving cars, like a windshields, are exposed to harsh environment of the road and gets dirty very fast from dust, pollen, birds' droppings, etc. Also, rain and condensation (fog, frost) would create additional obstacles for getting correct range data. Thus, the enclosure around LIDAR (which is usually a transparent glass dome) should be cleaned properly.

Recently Google proposed using an automatic wiper system that can detect when a dome 102 is dirty and begin a self-cleaning process (see FIG. 2). The wiping system includes multiple wipers 110A, 110B that are capable of rotating 360 degrees around the dome 102 protecting the sensors. According to the patent, the system could also have some sort of wiper fluid that is activated along with the wipers, so that whatever is dirtying up the dome 102 can quickly be cleaned off.

Again, Google chosen to use a century-old technology—wipers—to do the job.

Cleaning of Solar Panels:

Solar panels have to be cleaned periodically to preserve high efficiency of electricity generation. This problem is even more acute in dry regions, where rain is very rare. The solutions to this problem has been: manual labor and movable robots. Both solutions are costly, not safe, not convenient. NASA has suggested to use ultrasonic (bulk components) to shake up entire solar panel to “dust it off” (See FIG. 3). Obviously, the waste of energy with this method is considerable.

It is within this context that aspects of the present disclosure arise.

### 4. BRIEF DESCRIPTION OF THE DRAWINGS

Various aspects of the present disclosure will become apparent upon reading the following detailed description and upon reference to the accompanying drawings in which:

FIG. 1 is a schematic diagram illustrating an example of a prior art ultrasonic windshield cleaning system in which ultrasonic transducers are attached to glass substrates on the periphery.

FIG. 2 is a schematic diagram illustrating an example of a prior art LIDAR cleaning system in which the cover glass dome is cleaned by movable wipers.

FIG. 3 is a schematic diagram illustrating an example of a prior art solar panel cleaning system in which transducers are attached to the backside of the panel

FIGS. 4A-4C are schematic diagrams illustrating examples of transparent microstructured (patterned) piezoelectric transducers array in accordance with various aspects of the author's previous patent.

FIG. 5 depicts an embodiment of a microstructured (patterned) piezoelectric ultrasonic transducer design, where a patterned piezoelectric stack (with 2 electrode layers) is shown in cross-section view.

FIG. 6 is a schematic diagram illustrating example of a transparent piezoelectric transducer array according to aspects of the present disclosure.

FIG. 7 is a schematic diagram depicting a self-cleaning device for windshield based on transparent piezoelectric transducer array fabricated on essentially entire surface of the windshield, including viewable area

FIG. 8 Embodiment of self-cleaning device for LIDAR dome based on transparent piezoelectric transducer array fabricated on the surface of the dome.

FIG. 9 is a cross-sectional schematic diagram of a self-cleaning device for solar panel based on microstructured piezoelectric transducer array fabricated on the surface of the panel, where the microstructure has a triangular shape, which also reflects the light onto the panel surface

FIG. 10 is a schematic diagram showing an example of a system having two or more arrays of transparent transducers fabricated on a transparent substrate and coupled to a controller.

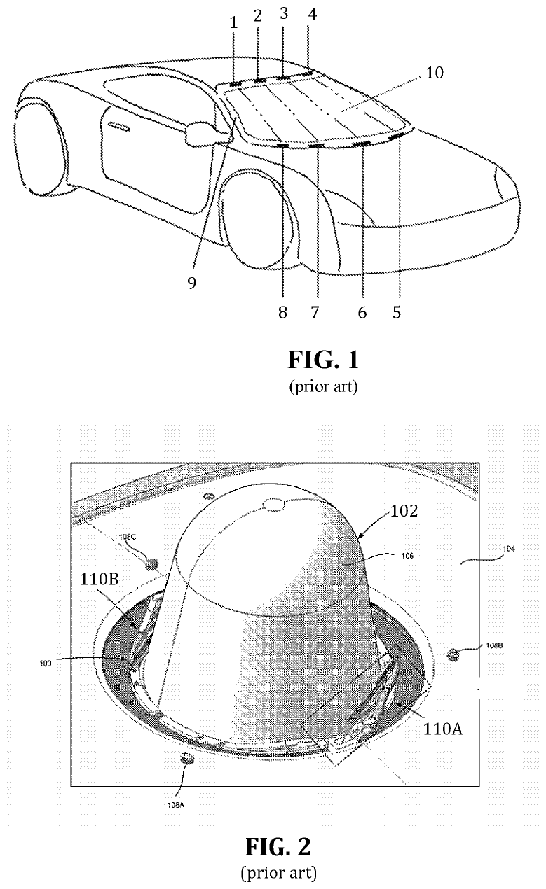

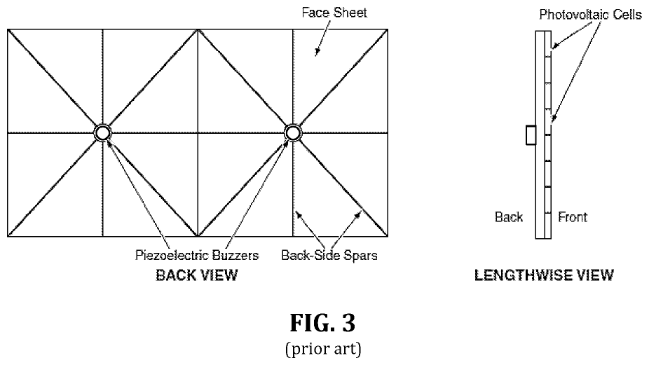

### 5. DETAILED DESCRIPTION

Although the following detailed description contains many specific details for the purposes of illustration, anyone of ordinary skill in the art will appreciate that many variations and alterations to the following details are within the scope of the invention. Accordingly, the aspects of the disclosure described below are set forth without any loss of generality to, and without imposing limitations upon, the claimed invention.

In the following detailed description, reference is made to the accompanying drawings, which form a part hereof, and in which is shown by way of illustration specific embodiments in which the invention may be practiced. In this regard, directional terminology, such as “top,” “bottom,” “front,” “back,” “first,” “second,” etc., is used with reference to the orientation of the figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Aspects of the present disclosure include use of transparent ultrasonic devices in optical components and devices for self-cleaning purposes. Ultrasonic energy emitted by a large array of piezoelectric transducers scattered across an entire glass or film surface to be cleaned in operation of the device (car, plane, solar panel, LIDAR, etc.) is used to dislodge contamination from the surface, or even prevent contamination from sticking to the surface in the first place. The same technology could be used to remove water droplets from the surface by moving them on the surface in the direction out of viewable area, or alternatively, evaporating them using ultrasonic energy. Thus the same technology could be effectively used also to de-ice or de-fog surface.

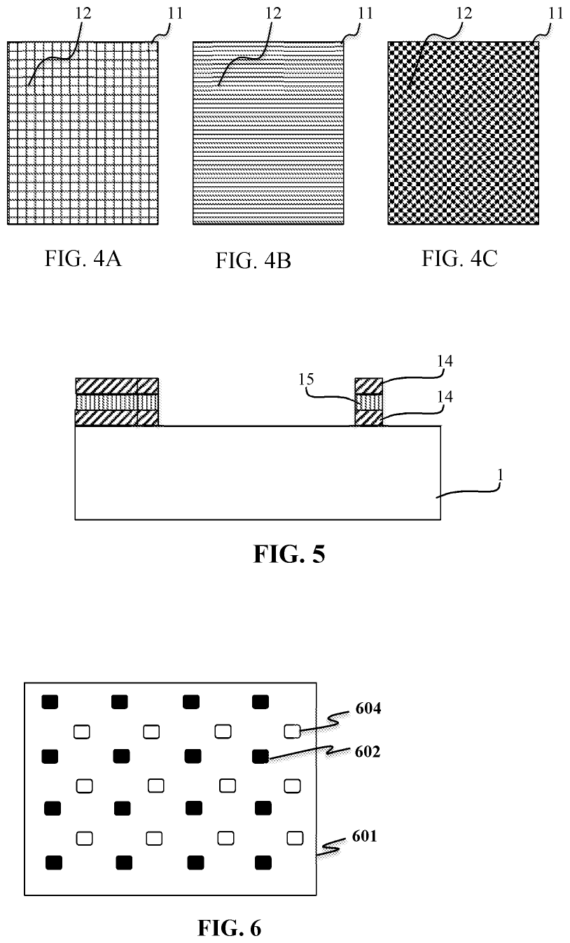

Such transducer, and method of their fabrication, have been proposed by authors earlier in PCT/US2016/015448, 991, U.S. Ser. No. 15/645,991, and U.S. 62/470,293, and may include a micro- or nano-structured mesh (12) as in FIG. 4A or a grating (12′), as in FIG. 4B, or an array (12″), as in FIG. 4C on the surface of a substrate (11), for example glass or polymer film. The criteria of transparency for such transducers could be met by optimizing a ratio of microstructure to an open area of the substrate. The criteria of visibility (unobstructed view) can be met by optimizing the feature size of the structure to be below recognition of a human eye at the required distances. That minimum feature size is usually less than 100 micron, sometimes less than 10 micron, though for the most demanding applications and good human vision, it could be less than 2.5 micron.

A micro- or nano-structured ultrasonic transducer could be made of a piezoelectric material sandwiched between 2 electrodes, e.g., as shown in FIG. 5. Moreover, both, a piezoelectric thin film (15) and electrodes (14), could be patterned on the substrate surface to yield a very transparent and invisible-to-the-eye device. In an alternative implementation, one or both electrodes could be deposited as a continuous layer of transparent conductive material, and only piezoelectric material would be patterned. Such transparent conduct material could be, e.g., Indium-Tin Oxide (ITO) or another transparent conductive oxide (TCO), or transparent organic conductors, or graphene, or silver nanowires or nanoparticles. Piezoelectric stack could be fabricated on Silicon or other high-temperature tolerant substrate, and then transfer-printed onto glass or polymer film, or other substrate.

Alternatively, piezoelectric transducer array could be fabricated from individual piezoelectric micro-chips, which are mass-transferred onto target substrate using pick-and-place or mass-transfer equipment, and subsequently attached to the prefabricated transparent conductor lines for powering up the circuit, as shown in FIG. 6. In the example shown schematically in FIG. 6, a transparent piezoelectric transducer array is fabricated from a number of piezoelectric micro-transducers 602 transferred onto a target substrate 601 and bonded to transparent conductor lines (not shown). As an example, for a display application, micro-LED chips 604 may be mass-transferred onto the same substrate. As an alternative example, micro-LED chips may be transferred onto the same substrate and attached to transparent conductor (not shown) for micro-LED display self-cleaning application.

Aspects of the present disclosure include, but are not limited to, the following embodiments.

### Embodiment-I

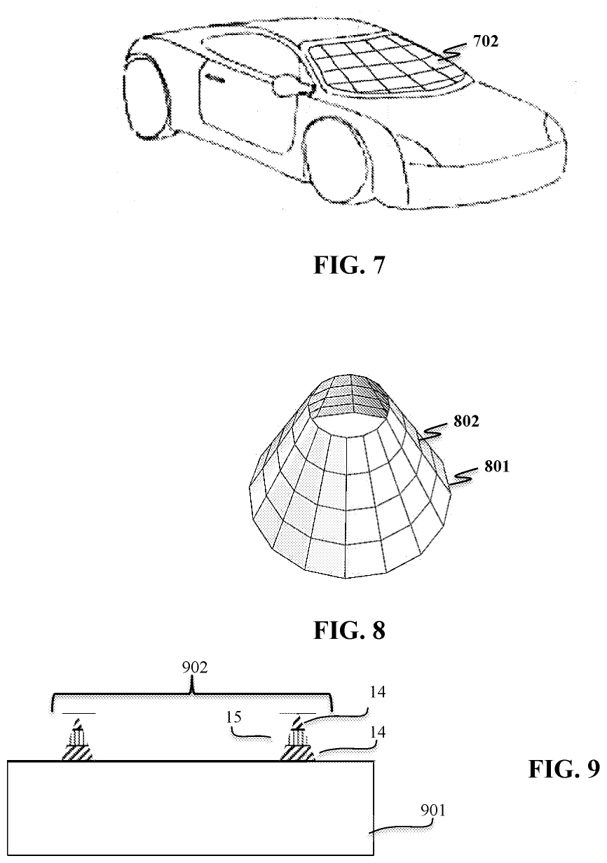

Essentially the entire viewable surface of the windshield of a car, plane, ship and other transportation vehicle may be covered with ultrasonic transducer array in a manner that is unobtrusive, transparent and invisible to the human eye (see FIG. 7). Such an array 702 of micro-piezoelectric transducers could be implemented as a continuous array of piezoelectric elements or as an array of separate micro-piezoelectric elements with an individual addressing capability.

Integrating ultrasonic transducers into the windshield enables to clean it on-demand without using movable parts. Wipers moving in front of the driver's eyes present a severe safety problem, especially with the heavy pouring rain, when one has to move them fast to clean the windshield from water. Wipers cannot do the proper cleaning of some bird's deposits, especially ones, which are “cooked” by the sun.

There are many advantages of the proposed technology for cleaning transparent devices. These include:
High efficiency of cleaning and energy savings due to ultrasonic transducers positioned in a very close proximity/right at the place of contamination—on the viewing area of a windshield
Integrating transparent ultrasonic emitting array with sensor array would allow to detect contamination and forward all energy to a specific spot to further optimize cleaning and reduce energy waste
Such devices could be integrated with superhydrophobic or superhydrophilic or photoactive surface treatment for better efficiency.
No mechanical movable fixtures are required.
High transparency; no tint

The integration of a self-cleaning ultrasonic device with the windshield glass can be done by laminating on windshield glass a piezoelectric array fabricated on the thin flexible glass or polymer film. The array may then be encapsulated with a transparent material (optically clear adhesive or similar) to provide environmental protection. Alternatively, the microstructure could be fabricated on thin transparent glass or polymer film and then laminated or bonded to glass product with microstructure side down, so the thin transparent substrate would act as protection layer against environment.

### Embodiment-II

An ultrasonic transducer array may be fabricated on a LIDAR dome. As illustrated in FIG. 8 the surface of a LIDAR dome 801 (enclosure/lens) may be covered with a piezoelectric transducer array 802. Alternatively, a transparent film or flexible glass substrate with such array may be laminated onto the dome surface. Part of an individually-addressable ultrasonic transducer array could be configured to emit ultrasonic signal, and another part—to detect ultrasonic signal. Detector array would sense contamination on the surface and software algorithm will trigger ultrasonic actuation or pulse directed to the place of contamination. Such ultrasonic transducer array can clean the surface of LIDAR dome on-demand and only contaminated surface, which would improve safety (immediate cleaning of contamination as soon as it appears on the surface), and with energy saving (cleaning only small portion of the dome surface). The laser scanning algorithm is optimized to avoid loss of signal due to blockage of light by piezoelectric transducers elements.

### Embodiment-III

An ultrasonic transducer array for cleaning LIDAR may have an aperiodic structure of piezoelectric features, so that light diffraction is avoided for the laser beam at specific wavelength of operation

### Embodiment-IV

An ultrasonic transducer array for cleaning LIDAR may have a periodic, 1D or 2D, structure of piezoelectric features, and the geometry of the microstructure (grating) is optimized to have one or multiple beams (diffractive orders), so that laser beam is diverted to larger angles, or multiple beams are used to scan the space simultaneously to build a 3D map of the area faster or more accurate.

### Embodiment-IV

An ultrasonic transducer array may be fabricated on a solar panel surface, such as a surface of a cover glass or polymer encapsulating film. Alternatively, the transparent film with such an array may be laminated on solar panel surface. Part of an individually-addressable ultrasonic transducer array could be configured to emit ultrasonic signals, and another part—to detect ultrasonic signals. The detector array would sense contamination on the surface and software algorithm trigger ultrasonic actuation or pulse directed to the place of contamination. Such an ultrasonic transducer array can clean the surface of solar panel on-demand and only contaminated surface, which would improve efficiency (cleaning of contamination as soon as it appears on the surface), and with energy saving (cleaning only small portion of the dome surface).

### Embodiment-V

A microstructured ultrasonic transducer array 902 for cleaning solar panel 901 may have a transduces with a piezoelectric thin film (15) and electrodes (14) in a triangular cross-sectional shape so that light would reflect from its surface onto the solar panel, as shown in FIG. 9. This would concentrate more light on solar cell surface and increase absorption efficiency of the solar panel.

### Embodiment-VI

An entire transparent substrate, e.g., a-windshield or window, may be divided into multiple areas with an array of individually powered ultrasonic transducers to save energy for forwarding ultrasonic power only to the area where contamination should be removed. Also, the individually addressable ultrasonic transducers or arrays of transducers allow creating an ultrasonic wave to dislodge and move contamination or water droplets on the surface in required direction.

### Embodiment-VII

An ultrasonic transducer array may be fabricated on a lighting fixture, for example, the headlight of a car or lighting enclosure of a street lighting, providing self-cleaning capability.

### Embodiment-VIII

An ultrasonic transducer array may be fabricated on the display cover glass or other encapsulation (environmental protection) layer of display, providing self-cleaning capability.

### Embodiment-IX

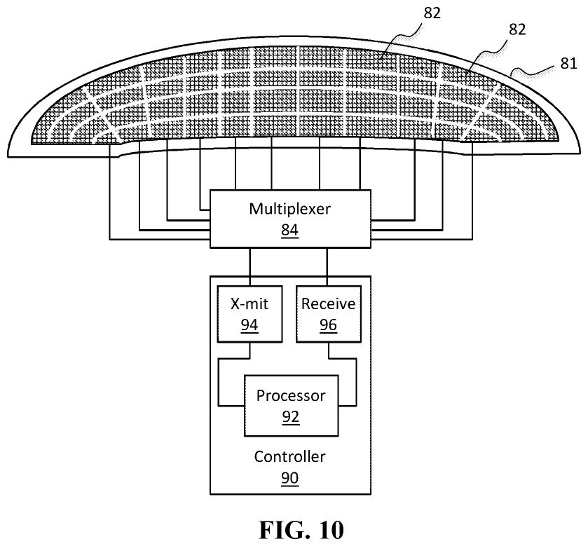

There are a number of ways to implement above Embodiments. FIG. 10 illustrates a system having two or more arrays of transparent transducers 82 fabricated on a transparent substrate 81 and coupled to a controller 90. The controller may include a processor 92 coupled to a transmit circuit 94 and a receive circuit 96. In the illustrated example, the arrays of transparent transducers 82 are operatively coupled to the controller 90 via a multiplexer 84. The multiplexer allows the transmit circuit 94 or the receive circuit 96 to be selectively coupled to individual arrays on the substrate 81. The processor 92 may be a programmable microprocessor, a microcontroller, an application specific integrated circuit (ASIC), field programmable gate array (FPGA), or other suitable device. It is noted that in some implementations, the multiplexer 84, processor 92, transmit circuit 94, and receive circuit 96 may be implemented in a common integrated circuit, such as a system on chip (SOC).

The transmit circuit 94 provides drive signals that drive the transducers 82 in response to drive instructions from the processor 92. Providing the drive instructions may involve interpretation of digital drive instructions and generation of corresponding analog output signals having sufficient amplitude to generate a desired ultrasound signal with a particular transducer. The drive signals may include switching signals that direct the multiplexer 84 to selectively couple the analog output signals to the particular transducer. By way of example and not by way of limitation, the processor 92 may send drive instructions to the transmit circuit 94 that direct the transmit circuit to couple drive signals to selected arrays in a sequence that sends transverse waves of ultrasound across the substrate from one end to the other.

The receive circuit receives 96 input signals from the transducers 82 and converts the received signals into a suitable form for signal processing by the processor. Conversion of the received signals may involve amplification of the received signals and conversion of the resulting amplified received signals from analog to digital form. The processor may be programmed or otherwise configured to perform digital signal processing on the resulting digital signals. Such digital signal processing may include time of flight analysis to determine a distance d to an object. Such time of flight analysis may involve determining an elapsed time Δt between the transmitting of acoustic pulses with one or more of the transducers 82 and detecting an echo of such pulses from the object with the same or different transducers 82. The processor 92 can calculate the distance d from the equation d=cΔt, where c is a known or estimated speed of sound.

### ADDITIONAL EMBODIMENTS

Aspects of the present disclosure are not limited to the above embodiments. For example, a transducer array for self-cleaning may be fabricated into or onto appliance surfaces (e.g., glass cooktops, oven windows, refrigerator shelves, microwave oven windows) during operation of these devices. In some implementations, the ultrasonic transducer may be engineered to also shield the device against radiofrequency (RF) radiation. Such engineering may include selection of thickness, linewidth and pitch of the patterned conductive electrodes in the ultrasonic transducers that make up the array.

Numerous other embodiments are within the scope of the present disclosure.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

1. A self-cleaning device, comprising:
a transparent substrate;
a piezoelectric transducer array formed on essentially entire transparent substrate surface;
including a central area of the transparent device; and
an electronic system configured to actuate the piezoelectric transducer array to clean a surface of the substrate.

2. The device of claim 1 wherein the piezoelectric transducer array is a combination of patterned layers of metal electrodes and piezoelectric material.

3. The device of claim 1 wherein the piezoelectric transducer array includes a number of piezoelectric transducer chips attached to such substrate at specific places and connected to a transparent conductor lines fabricated on the substrate.

4. The device of claim 1 wherein the piezoelectric transducer array has features of less than 100 microns.

5. The device of claim 1 wherein the piezoelectric transducer array has features of less than 10 microns.

6. The device of claim 1 wherein the piezoelectric transducer array has features of less than 5 microns.

7. The device of claim 1 wherein the piezoelectric transducer array includes one or more transducers that are formed on transparent polymer film, which is laminated onto a substrate.

8. The device of claim 1 wherein the piezoelectric transducer array includes transducers formed on transparent glass film, which is laminated onto a substrate or embedded into product glazing structure.

9. The device of claim 1 wherein the piezoelectric transducer array includes transducers that are encapsulated with a thin transparent polymer film or glass.

10. The device of claim 1 wherein the piezoelectric transducer array includes a patterned piezoelectric material, wherein the patterned piezoelectric material includes an array of individually-addressable piezoelectric transducers.

11. The device of claim 1 wherein some transducers in the piezoelectric transducer array are configured to emit ultrasonic energy and some transducers in the piezoelectric transducer array are configured to detect ultrasonic energy (sensors), so that the control system can obtain information about location of contamination on the substrate surface and direct ultrasonic energy only to contaminated area.

12. The device of claim 1 wherein the substrate is an enclosure of a LIDAR.

13. The device of claim 1 wherein the substrate is an enclosure of a radar.

14. The device of claim 1 wherein the substrate is an enclosure or lens of light detector or camera.

15. The device of claim 1 wherein the substrate is an enclosure of lighting device in a vehicle.

16. The device of claim 1 wherein the substrate is an enclosure of street lighting.

17. The device of claim 1 wherein the substrate is an enclosure of solar panel.

18. The device of claim 1 wherein the substrate is a windshield or window, or sunroof of a car, plane, ship, drone or other transportation vehicle.

19. The device of claim 1 wherein the substrate is a prescription or sunglasses, visors or helmets.

20. The device of claim 1 wherein the substrate is a window of a building.

21. The device of claim 1, wherein the substrate is a surface of an appliance.

22. The device of claim 22, wherein the appliance includes a glass cooktop, oven window, refrigerator shelf, or microwave oven window.

23. The device of claim 1 wherein the piezoelectric transducer array is aperiodic to avoid light diffraction.

24. The device of claim 1, wherein the piezoelectric transducer array includes a microstructure, wherein microstructure is periodic and pitch is chosen to create one or multiple diffraction orders.

25. A method of fabricating a self-cleaning transparent surface, comprising:
fabricating an ultrasonic transducers array on a flexible on essentially an entire surface of a transparent substrate, including a central area;
attaching such substrate to a transparent surface to be cleaned; and
actuating such transducers in order to emit ultrasonic energy towards the surface.

26. A method according to 23 wherein the transducers are configured to remove contamination from the surface when activated.

27. A method according to 23 wherein the transducers are configured to remove water in any phase of water, including liquid, water drops, fog or ice, when activated.

28. A method according to 23 wherein such transparent substrate is LIDAR enclosure.

29. A method according to 23 wherein such transparent substrate is windshield of a transportation vehicle.

30. A method according to 23 wherein such transparent substrate is a window of transportation vehicle or architectural building.

31. A method according to 23 wherein such transparent substrate is enclosure of solar panel.

32. A method according to 23 wherein such transparent substrate is visor, goggle, helmet or glasses.
